(19) United States
(12) Patent Application Publication
(10) Pub. No.: US 2016/0155904 A1
(43) Pub. Date: Jun. 2, 2016

(54) HIGH-CONDUCTIVITY THIN-FILM STRUCTURE FOR REDUCING METAL CONTACT RESISTANCE

(71) Applicant: National Chung Shan Institute of Science and Technology, Longtan Township (TW)

(72) Inventors: SHIH-CHANG LIANG, LONGTAN TOWNSHIP (TW); KE-DING LI, LONGTAN TOWNSHIP (TW); CHAO-NAN WEI, LONGTAN TOWNSHIP (TW); CUO-YO NI, LONGTAN TOWNSHIP (TW); HUI-YUN BOR, LONGTAN TOWNSHIP (TW)

(21) Appl. No.: 14/556,701

(22) Filed: Dec. 1, 2014

(51) Int. Cl. H01L 33/42; H01L 29/43; H01L 31/0224

(52) U.S. Cl. CPC H01L 33/42; H01L 31/022483; H01L 31/022466; H01L 29/43

(57) ABSTRACT

A high-conductivity thin-film structure for reducing metal contact resistance is disposed between a substrate and at least a metal electrode of a photoelectric component, characterized in that the thin-film structure has a first conductive layer and a second conductive layer, wherein the first conductive layer is a non-crystalline transparent conductive thin-film deposited on a lateral surface of the substrate, and the second conductive layer is a crystalline transparent conductive thin-film deposited on a lateral surface of the first conductive layer, wherein another surface of the second conductive layer is in contact with the metal electrode to serve as a conduction medium between the first conductive layer and the metal electrode. Therefore, the thin-film structure exhibits high conductivity, high transmittance, low contact resistance toward the metal electrode, and insusceptibility to unfavorable effects of coarseness of the surface of the substrate.

### FIELD OF TECHNOLOGY

The present invention relates to conductive thin-films for use with photoelectric components, and more particularly, to a thin-film structure whereby a conductive thin-film manifests low contact resistance and high transmittance characteristics and matches a metal electrode, regardless of the coarseness of the surface of a substrate.

### BACKGROUND

A conventional photoelectric component, such as a light-emitting diode (LED), a flat panel display (FPD), a solar cell, a touchscreen, or an e-book, has therein a transparent conductive thin-film which serves as a conduction bridge and thus is an indispensable structure. The conductive thin-film must exhibit satisfactory conductivity characteristics and light transmittance. Conventional conductive thin-films for use with photoelectric products come in two categories, namely crystalline conductive thin-films and non-crystalline conductive thin-films. Crystalline conductive thin-films surpass non-crystalline conductive thin-films in popularity with consumers.

Conventional crystalline conductive thin-films attain excellent conductivity characteristics and light transmittance by effectuating high crystallization and satisfactory preferred directions. In a lot of photoelectric components, low-temperature coating or metal hot-pressing enables a crystalline conductive thin-film to diffuse in the presence of a metal by means of a crystal boundary to thereby reduce the contact resistance of the crystalline conductive thin-film and the metal and enhance the efficiency of the operation of the photoelectric components. However, the photoelectric components are confronted with a problem, that is, an overly coarse surface of the substrate which the photoelectric components are disposed on causes the crystallization of the crystalline conductive thin-film to deteriorate and thus causes the crystalline conductive thin-film to grow in unsatisfactory preferred directions, thereby compromising the electrical properties of the conductive thin-film. To overcome the aforesaid drawback of conventional crystalline conductive thin-films, the prior art discloses increasing the required thickness of crystalline conductive thin-films to achieve optimal conductivity characteristics at the cost of light transmittance. As a result, with the light transmittance being compromised, so is the performance of the photoelectric components.

In the situation where non-crystalline conductive thin-films are produced at room temperature, the non-crystalline conductive thin-films manifest the same degree of satisfactory conductivity, high thermal stability, and high light transmittance as the crystalline conductive thin-films do and thus are especially effective in solving the aforesaid problem with the effect of the coarseness of the surface of the substrate on the conductivity of the conductive thin-films. In addition, since a non-crystalline conductive thin-film lacks a crystal boundary and thus fails to diffuse in the presence of a metal, thereby leading to a great contact resistance between a metal electrode and the non-crystalline conductive thin-film as well as deterioration of the efficiency of the operation of the photoelectric components.

### SUMMARY

In view of the aforesaid drawbacks of the prior art, it is an objective of the present invention to provide a thin-film structure which manifests high conductivity and thus is effective in reducing metal contact resistance to thereby enhance the performance of conductive thin-films for use with photoelectric components

Another objective of the present invention is to provide a high-conductivity thin-film structure adapted to reduce metal contact resistance and disposed in photoelectric components in a manner that the thin-film structure manifests satisfactory physical properties, such as high conductivity, high transmittance, and low contact resistance, regardless of the coarseness of the surface of the substrate which the photoelectric components are disposed on, so as to enable the photoelectric components to achieve optimal operation efficiency.

In order to achieve the above and other objectives, the present invention provides a high-conductivity thin-film structure for reducing metal contact resistance, disposed between a substrate and at least a metal electrode of a photoelectric component, characterized in that: the thin-film structure has a first conductive layer and a second conductive layer, wherein the first conductive layer is a non-crystalline transparent conductive thin-film deposited on a lateral surface of the substrate, and the second conductive layer is a crystalline transparent conductive thin-film deposited on a lateral surface of the first conductive layer, wherein another surface of the second conductive layer is in contact with the metal electrode to serve as a conduction medium between the first conductive layer and the metal electrode.

The first conductive layer and the second conductive layer are formed by sputtering or evaporation. The second conductive layer is made of a compound which contains indium oxide or zinc oxide and is 25 nm-150 nm thick. The first conductive layer is 100 nm-500 nm thick.

### BRIEF DESCRIPTION

Objectives, features, and advantages of the present invention are hereunder illustrated with specific embodiments in conjunction with the accompanying drawings, in which:

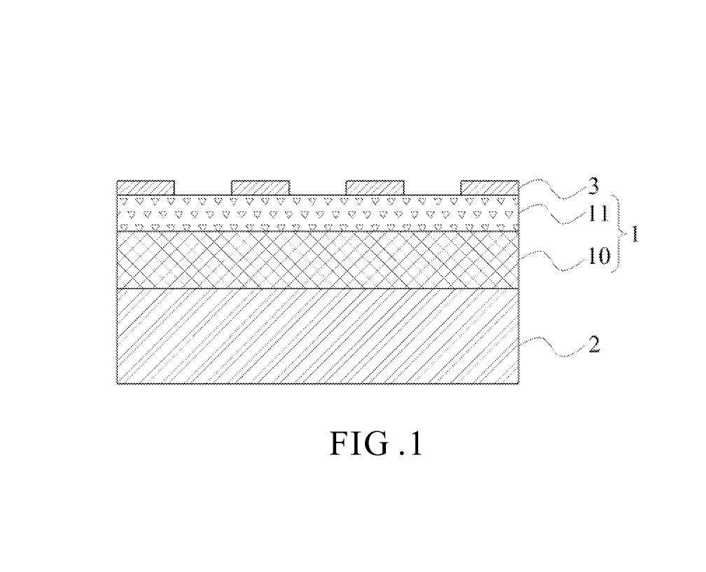

FIG. 1 is a cross-sectional view of a preferred embodiment of the present invention;

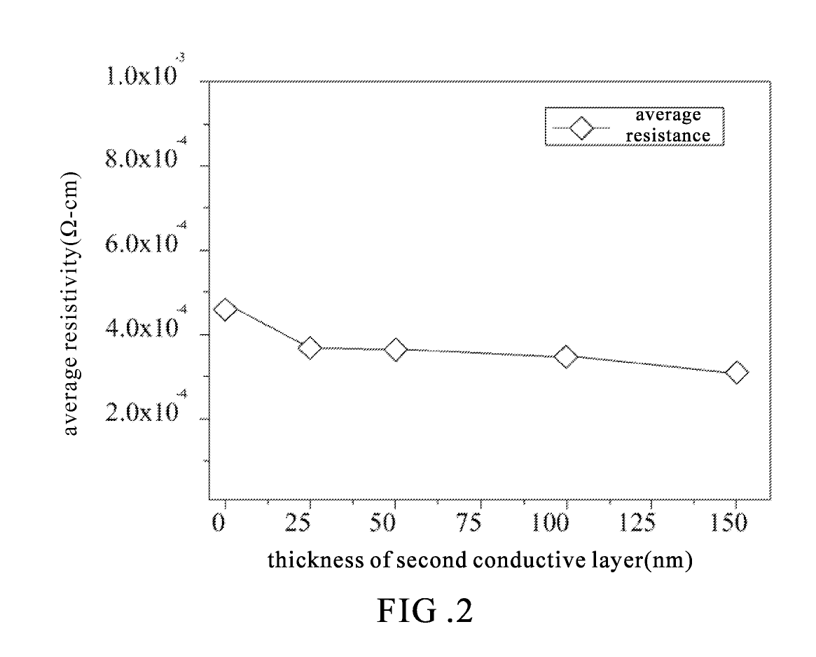

FIG. 2 is a graph of resistance against thickness of a second conductive layer according to the preferred embodiment of the present invention; and

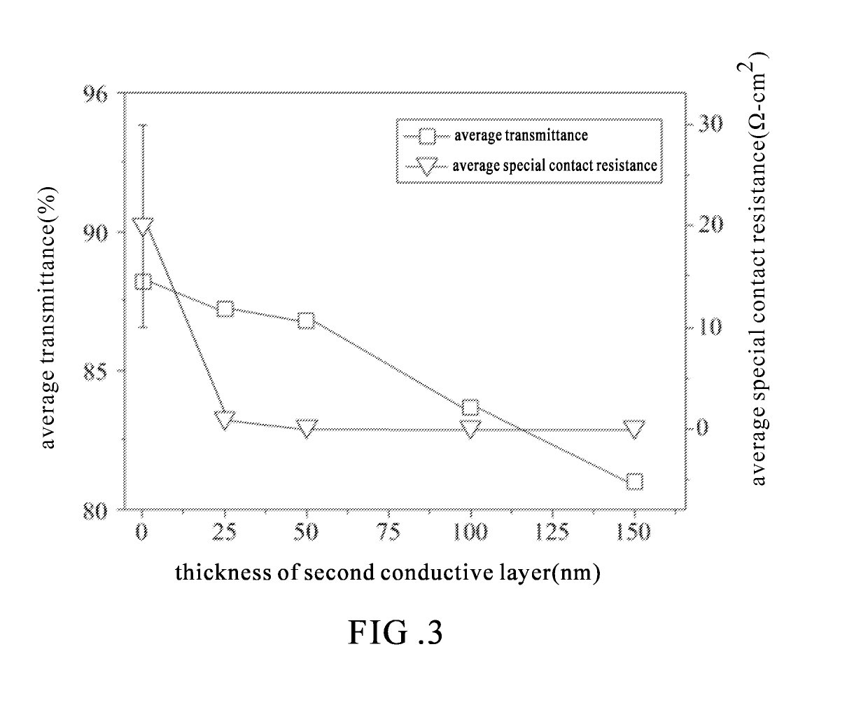

FIG. 3 is a graph of light transmittance and contact resistance against thickness of the second conductive layer according to the preferred embodiment of the present invention.

### DETAILED DESCRIPTION

Referring to FIGS. 1, 2, 3, there are shown in FIG. 1 a cross-sectional view of a preferred embodiment of the present invention, in FIG. 2 a graph of resistance against thickness of a second conductive layer according to the preferred embodiment of the present invention, and in FIG. 3 a graph of light transmittance and contact resistance against thickness of the second conductive layer according to the preferred embodiment of the present invention. A high-conductivity thin-film structure 1 for reducing metal contact resistance according to the present invention is disposed between a substrate 2 and at least a metal electrode 3 of a photoelectric component or a semiconductor component (not shown), wherein the metal electrode 3 is formed by a low-temperature baking and curing process, but the present invention is not limited thereto.

The thin-film structure 1 has a first conductive layer 10 and a second conductive layer 11. The first conductive layer 10 is a non-crystalline transparent conductive thin-film and is disposed on a lateral surface of the substrate 2 by physical vapor deposition, but the present invention is not limited thereto. With the first conductive layer 10 being amorphous, structurally unorganized, and lacking any long-distance organized structure in an atomic scale, the first conductive layer 10 is insusceptible to the coarseness of the surface of the substrate 2 upon completion of the deposition process, thereby exhibiting satisfactory conductivity. Preferably, the first conductive layer 10 is 100 nm-500 nm thick and is formed on a lateral surface of the substrate 2 by physical vapor deposition, such as sputtering or evaporation.

The second conductive layer 11 is a crystalline transparent conductive thin-film and is disposed on a lateral surface of the substrate 2 by physical vapor deposition, but the present invention is not limited thereto, wherein the lateral surface of the substrate 2 is opposite the first conductive layer 10. The other side of the second conductive layer 11 is in contact with the metal electrode 3 to serve as the conduction medium between the first conductive layer 10 and the metal electrode 3. Preferably, the second conductive layer 11 is made of a compound which contains indium oxide or zinc oxide, such as ITO, AZO, or GZO. The second conductive layer 11 is 25 nm to 150 nm thick and is deposited and formed on the first conductive layer 10 by sputtering or evaporation. The second conductive layer 11 is made of a crystalline metal and thus exhibits satisfactory physical properties, such as high conductivity and high transmittance, so as to serve as the conduction medium between the first conductive layer 10 and the metal electrode 3 to thereby achieve optimal operation efficiency. Due to the first conductive layer 10 and the second conductive layer 11, the thin-film structure 1 is a bilayer structure, wherein the physical properties of the first conductive layer 10 are effective in precluding the effect of the coarseness of the surface of the substrate 2 on the conductivity of the second conductive layer 11, whereas the physical properties of the second conductive layer 11 are effective in reducing the contact resistance of the thin-film structure 1 toward the metal electrode 3, thereby enhancing their conductivity and transmittance.

The results of the measured conductivity, light transmittance and contact resistance against the thickness of the second conductive layer 11 of the thin-film structure 1 are discussed below. The first conductive layer 10 is made of IZO and is deposited, by sputtering, on the substrate 2 made of glass, wherein the sputtering process is performed on the first conductive layer 10 with target materials, namely In₂O₃ and 10 wt. % ZnO, at basic vacuum of 5.0×10⁻⁶ Torr, operating pressure of 2.5˜10×10⁻³ Torr, and power of 75˜150 W, in the presence of argon which functions as the process gas, such that the first conductive layer 10, which is 300 nm or so in thickness, is deposited on the substrate 2. The second conductive layer 11 is made of ITO and is deposited, by sputtering, on the first conductive layer 10, wherein the sputtering process is performed on the second conductive layer 11 with target materials, namely In₂O₃ and 10 wt. % SnO₂ (ITO) at basic vacuum of 5.0×10⁻⁶ Torr, operating pressure of 2.5˜10×10⁻³ Torr, and power of 75˜150 W, in the presence of argon which functions as the process gas, wherein the temperature of the substrate 2 is 75˜200° C. Multiple thin-film structures are produced by the aforesaid process, wherein the thin-film structures are characterized in that: the second conductive layers 11 which differ in thickness are deposited on the first conductive layer 10 so as to evaluate the effect of the thickness of the second conductive layer on physical properties, such as resistivity, transmittance, and contact resistance. Referring to FIG. 2, when the second conductive layer 11 is 25 nm, 50 nm, 100 nm, and 150 nm thick, its resistivity can be as low as 4×10⁻⁴ Ω-cm which approximates to the resistivity achievable when only the first conductive layer 10 is present, thereby proving that the presence of the second conductive layer 11 above the first conductive layer 10 makes no impact on the overall conductivity of the thin-film structure 1. Referring to FIG. 3, the light transmittance of the second conductive layer 11 varies with its thickness. When the second conductive layer 11 is 25 nm, 50 nm, 100 nm, and 150 nm thick, its average transmittance equals 87.21%, 86.76%, 83.62%, and 80.95%, respectively, in the range of visible light wavelengths. On the contrary, the sole presence of the first conductive layer 10 yields an average transmittance of 88.15%. Hence, it proves that even if the second conductive layer 11 is also present, it will cause the thin-film structure to have an average transmittance as high as 80% without compromising its operation efficiency within the photoelectric components.

The metal electrode 3 is provided in the plural, whereas the second conductive layer 11 is coated with silver paste to define five regions each with an area of 6 mm² and undergo baking and curing at 100˜150° C., such that the metal electrodes 3 are 8 μm˜10 μm thick. Referring to FIG. 3, the contact resistance between the second conductive layer 11 and the metal electrodes 3 is measured. In the sole presence of the first conductive layer 10, the average contact resistance equals 20.01 Ωcm², with an error of 10 Ωcm², thereby exhibiting unsatisfactory contact resistance reproducibility. When the second conductive layer 11 is 25 nm, 50 nm, 100 nm, and 150 nm thick, its average contact resistance equals 0.87 Ωcm², 7.1×10⁻² Ωcm², 3.9×10⁻² Ωcm², and 7×10⁻² cm², respectively, with its error diminished significantly, thereby exhibiting optimal contact resistance reproducibility. The table below shows the results regarding the average resistivity, average light transmittance, and average contact resistance of the metal electrodes 3 versus the thickness of the first and second conductive layers.

| | second | | | | |
|---|---|---|---|---|---|
| first conductive | conductive | | average | average contact | contact |
| layer thickness | layer thickness | average | transmittance | resistance | resistance |
| (nm) | (nm) | resistivity (Ω-cm) | (%) | (Ωcm²) | error (Ωcm²) |
| 300 | 0 | 4.63 × 10⁻⁴ | 88.15 | 20 | 10 |
| 300 | 25 | 3.73 × 10⁻⁴ | 87.21 | 0.87 | 0.4 |
| 300 | 50 | 3.67 × 10⁻⁴ | 86.76 | 0.071 | 0.06 |
| 300 | 100 | 3.48 × 10⁻⁴ | 83.62 | 0.039 | 0.032 |
| 300 | 150 | 3.12 × 10⁻⁴ | 80.95 | 0.07 | 0.005 |

As indicated above, when the second conductive layer 11 is 50 nm thick, the thin-film structure 1 manifests the best light transmittance and contact resistance, and thus the thin-film structure 1 is effective in eliminating the effects of the coarseness of the surface of the substrate 2 on conductivity and exhibits satisfactory physical properties, such as low contact resistance and high transmittance, such that the photoelectric components have optimal operation efficiency.

The present invention is disclosed above by preferred embodiments. However, the preferred embodiments are illustrative of the present invention only, but should not be interpreted as restrictive of the scope of the present invention. Hence, all equivalent changes and modifications made to the aforesaid embodiments without departing from the spirit and scope of the present invention should fall within the scope of the present invention. Accordingly, the legal protection for the present invention should be defined by the appended claims.

1. A high-conductivity thin-film structure for reducing metal contact resistance, disposed between a substrate and at least a metal electrode of a photoelectric component, comprising:
a first conductive layer; and
a second conductive layer, wherein the first conductive layer is a non-crystalline transparent conductive thin-film deposited on a lateral surface of the substrate, and the second conductive layer is a crystalline transparent conductive thin-film deposited on a lateral surface of the first conductive layer, wherein another surface of the second conductive layer is in contact with the metal electrode to serve as a conduction medium between the first conductive layer and the metal electrode.

2. The thin-film structure of claim 1, wherein the first conductive layer and the second conductive layer are formed by one of sputtering and evaporation.

3. The thin-film structure of claim 2, wherein the second conductive layer is made of a compound which contains one of indium oxide and zinc oxide.

4. The thin-film structure of claim 3, wherein the second conductive layer is 25 nm˜150 nm thick.

5. The thin-film structure of claim 4, wherein the first conductive layer is 100 nm˜500 nm thick.
